(19) United States
(12) Patent Application Publication
(10) Pub. No.: US 2023/0077993 A1
(43) Pub. Date: Mar. 16, 2023

(54) ELECTRONIC DEVICE HAVING ELECTRONIC COMPONENTS

(71) Applicant: InnoLux Corporation, Miao-Li County (TW)

(72) Inventors: Li-Wei SUNG, Miao-Li County (TW); Chung-Le CHEN, Miao-Li County (TW); Hung-Kun CHEN, Miao-Li County (TW); Ting-Yao CHU, Miao-Li County (TW)

(21) Appl. No.: 17/818,085

(22) Filed: Aug. 8, 2022

(30) Foreign Application Priority Data
Sep. 10, 2021 (CN) 202111060484.5

(51) Int. Cl. H01L 27/12; H01L 25/18

(52) U.S. Cl. CPC H01L 27/124; H01L 25/18

(57) ABSTRACT

An electronic device includes multiple electronic component groups and a control circuit. The control circuit is electrically connected the electronic component groups. One of the electronic component groups receives two power signals from the control circuit through a first signal receiving end, a second signal receiving end, and a third signal receiving end.

### CROSS REFERENCE TO RELATED APPLICATIONS

This application claims the benefit of China Application No. 202111060484.5, filed on Sep. 10, 2021, the entirety of which is incorporated by reference herein.

### BACKGROUND OF THE DISCLOSURE

### Field of the Invention

The present invention relates to an electronic device, and, in particular, to an electronic device having electronic components.

### Description of the Related Art

With the increasing size of electronic devices, the number of electronic components driven by the circuit board has also increased. In the prior art, the transmission of current may be different as the transmission path is longer, so that the current flowing through the electronic components at different positions will be different and appear unevenly bright and dark on the display, thereby affecting the image quality.

### BRIEF SUMMARY OF THE DISCLOSURE

An embodiment of the present disclosure provides an electronic device. The electronic device includes multiple electronic component groups and a control circuit. The control circuit is electrically connected the electronic component groups. One of the electronic component groups receives two power signals from the control circuit through a first signal receiving end, a second signal receiving end, and a third signal receiving end.

### BRIEF DESCRIPTION OF THE DRAWINGS

The disclosure can be more fully understood by reading the subsequent detailed description with references made to the accompanying figures. It should be understood that the figures are not drawn to scale in accordance with standard practice in the industry. In fact, it is allowed to arbitrarily enlarge or reduce the size of components for clear illustration. This means that many special details, relationships and methods are disclosed to provide a complete understanding of the disclosure.

FIG. 1 is a schematic diagram of an electronic device 100 in accordance with some embodiments of the present disclosure.

FIG. 2 is a schematic diagram of one of many electronic components of the electronic device 100 in FIG. 1 in accordance with some embodiments of the present disclosure.

FIG. 3 is a schematic diagram of one of the multiple electronic components of the electronic device 100 in FIG. 1 in accordance with some embodiments of the present disclosure.

FIG. 4 is a schematic diagram of one of the multiple electronic components of the electronic device 100 in FIG. 1 in accordance with some embodiments of the present disclosure.

FIG. 5 is a schematic diagram of one of the multiple electronic components having a circuit cut-off region of the electronic device 100 in FIG. 1 in accordance with some embodiments of the present disclosure.

FIG. 6 is a circuit layout diagram of some electronic components in FIG. 5 in accordance with some embodiments of the present disclosure.

FIG. 7 is a circuit layout diagram of some electronic components in FIG. 5 in accordance with some embodiments of the present disclosure.

FIG. 8 is a circuit layout diagram of some electronic components in FIG. 5 in accordance with some embodiments of the present disclosure.

FIG. 9 is a schematic diagram of one of the multiple electronic components of the electronic device 100 in FIG. 1 in accordance with some embodiments of the present disclosure.

### DETAILED DESCRIPTION OF THE DISCLOSURE

In order to make the above purposes, features, and advantages of some embodiments of the present disclosure more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” and/or “include” used in the present disclosure are used to indicate the existence of specific technical features, values, method steps, operations, units and/or components. However, it does not exclude that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

It should be noted that the technical features in different embodiments described in the following can be replaced, recombined, or mixed with one another to constitute another embodiment without departing from the spirit of the present disclosure.

The electronic device in the present disclosure can be any suitable type of device, such as a touch display device, an antenna device, a tiled device, a sensing device, a flexible device, etc., but is not limited thereto. The electronic device described in the present disclosure is a touch display device with touch and display functions, and the display device may include liquid crystal (LC), light-emitting diode (LED), quantum dots (QDs), fluorescence, phosphor, other suitable materials or a combination of the above materials, but is not limited thereto. The light-emitting diode may include organic light-emitting diode (OLED), inorganic light-emitting diode, micro-LED, mini-LED, quantum dot light-emitting diode (QLED, QDLED), other suitable materials or a combination of the above materials, but is not limited thereto. The tiled device may be, for example, a tiled display device or a tiled antenna device, but is not limited thereto. In addition, the display device in the electronic device may be a color display device or a monochrome display device, and the shape of the electronic device may be rectangular, circular, polygonal, a shape with curved edges, or other suitable shapes. In addition, the electronic device described below uses, as an example, the sensing of a touch through an embedded touch device, but the touch-sensing method is not limited thereto, and another suitable touch-sensing method can be used provided that it meets all requirements.

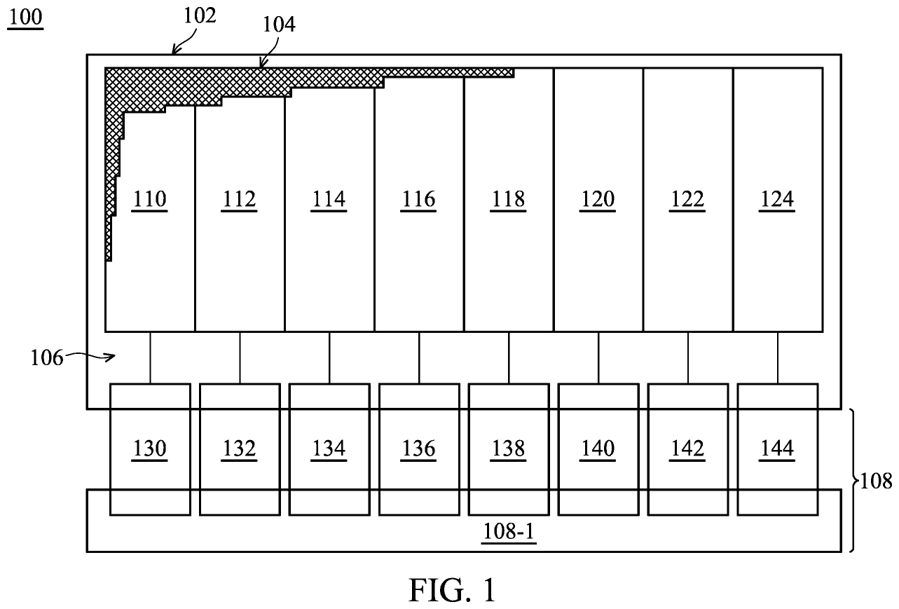

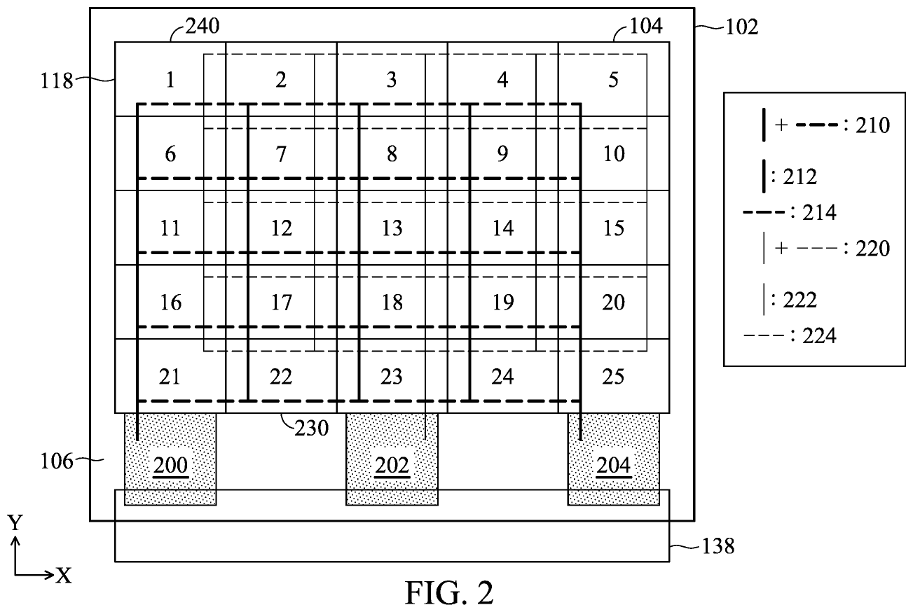

FIG. 1 is a schematic diagram of an electronic device 100 in accordance with some embodiments of the present disclosure. As shown in FIG. 1, the electronic device 100 includes multiple electronic component groups and a control circuit 108. The control circuit 108 is electrically connected to the multiple electronic component groups, such as an electronic component group 110, an electronic component group 112, an electronic component group 114, an electronic component group 116, an electronic component group 118, an electronic component group 120, an electronic component group 122, and an electronic component group 124, but the present disclosure is not limited thereto. FIG. 2 is a schematic diagram of one of many electronic components of the electronic device 100 in FIG. 1, in accordance with some embodiments of the present disclosure. In FIG. 2, the electronic component group 118 is used as an example, and the electronic component group 118 may include, for example, multiple electronic components, such as electronic components 1 to 25, but the present disclosure is not limited thereto. In some embodiments, for example, multiple electronic component groups may be sequentially arranged in one direction, but the present disclosure is not limited thereto. In some embodiments (not shown), multiple electronic component groups may be arranged in an array or staggered arrangement, for example. The number or arrangement of the electronic component groups may be changed according to the requirement. The electronic components of the present disclosure may include, for example, light emitting components, display components, sensing components, antenna components, or other suitable components.

In some embodiments, the control circuit 108 may include, for example, multiple control units (such as a control unit 130, a control unit 132, a control unit 134, a control unit 136, a control unit 138, a control unit 140, a control unit 142, and a control unit 144) and/or a power-supply circuit 108-1, but the present disclosure is not limited thereto. In some embodiments, the multiple control units may be electronically connected between the power-supply circuit 108-1 and the electronic component groups, for example, but the present disclosure is not limited thereto. In some embodiments, different electronic component groups can receive signals provided by the power-supply circuit 108-1 through the control units electrically connected to the electronic component groups, but the present disclosure is not limited thereto. In some embodiments, for example, the number of control units is the same as the number of electronic component groups, and one control unit can be electrically connected to one electronic component group, but the present disclosure is not limited thereto. Specifically, the control unit 130, the control unit 132, the control unit 134, the control unit 136, the control unit 138, the control unit 140, the control unit 142 and the control unit 144 are electrically connected to the electronic component group 110, the electronic component group 112, the electronic component group 114, the electronic component group 116, the electronic component group 118, the electronic component group 120, the electronic component group 122 and the electronic component group 124, respectively, but the present disclosure is not limited thereto. In other embodiments (not shown), the control circuit 108 may include, for example, multiple power-supply circuits, and different control units may be electrically connected to, for example, different power-supply circuits 108-1, but the present disclosure is not limited thereto.

In some embodiments, one of the electronic component group, such as the electronic component group 118, may receive two power signals from the control unit 138 through a first signal receiving end 200, a second signal receiving end 202, and a third signal receiving end 204. The two power signals may include, for example, a working voltage (e.g., VDD), a common connection voltage (e.g., VSS), or other suitable voltages, respectively, but the present disclosure is not limited thereto. Similarly, the other electronic component groups 110, 112, 114, 116, 120, 122, and 124 may receive the two power signals from the control units 130, 132, 134, 136, 140, 142, and 144, respectively, but the present disclosure is not limited thereto. In some embodiments, the voltages between the two power-supply signals may have a voltage difference. For example, the first power signal may be, for example, a positive voltage, and the second power signal may be, for example, a ground voltage (GND), a negative voltage, or the positive voltage, but the present disclosure is not limited thereto. In some embodiments, one of the electronic component groups may include multiple electronic components. For example, the electronic component group 118 in FIG. 2 may include multiple electrical components 1˜25. When the electronic components are light-emitting components, the electronic components 1˜25 may include at least one transistor (not shown) and at least one light-emitting diode (not shown), respectively, but the present disclosure is not limited thereto. In some embodiments, the electronic components 1˜25 are electrically connected to the two power signals respectively, for example, the working voltage and the common connection voltage, but the present disclosure is not limited thereto. The electronic components 1˜25 can drive the light-emitting diodes in the electronic components through the voltage difference between the two power signals, but the present disclosure is not limited thereto. The light-emitting diode may include organic light-emitting diode (OLED), inorganic light-emitting diode, micro-LED, mini-LED, quantum dot light-emitting diode (QLED, QDLED), other suitable materials or a combination of the above materials, but is not limited thereto.

In some embodiments, the electronic device 100 may further include a circuit substrate 102. The circuit substrate 102 may have an active area 104 and an inactive area 106 adjacent to the active area 104. In some embodiments, the inactive area 106 may, for example, surround the active area 104 or be adjacent to at least one side of the active area 104, but the present disclosure is not limited thereto. In some embodiments, multiple electronic component groups (such as the electronic component groups 110, 112, 114, 116, 118, 120, 122, and 124) may be disposed on the active area 104. In some embodiments, the control circuit 108 (such as the control units 130, 132, 134, 136, 138, 140, 142, and 144) may be disposed on the inactive area 106. In other words, the active area 104 can be defined as an area where electronic component groups are disposed. The inactive area 106 can be defined as an area where external wirings (not shown) are disposed. In some embodiments, the circuit substrate 102 may include an array substrate or a circuit board, but the present disclosure is not limited thereto. The circuit substrate 102 can be applied to a panel or a backlight module, but is not limited thereto. The panel includes, for example, a display panel, a touch panel, a detection panel, an antenna panel, or other suitable panels.

In the embodiments of FIG. 2, the electronic component group 118 includes 25 electronic components as an example, and the electronic components 1˜14 can be arranged in an array, for example, but is not limited thereto. The number of electronic components in an electronic component group or the arrangement of the electronic components can be adjusted according to the requirement. It should be noted that FIG. 2 only uses electronic components 1˜25 to illustrate electronic components located in different areas, but the present disclosure is not limited thereto. More electronic components can be selectively inserted between these electronic components 1˜25.

In the embodiments of FIG. 1 and FIG. 2, the electronic component group 118 has a first side 230 and a second side 240 opposite the first side 230. The first signal receiving end 200, the second signal receiving end 202, and the third signal receiving end 204 can be disposed on the inactive area 106 and adjacent to the first side 230 of the electronic component group 118. In some embodiments, the control unit 138 may include a rigid printed circuit board, a flexible printed circuit (FPC) board, or other suitable components, but is not limited thereto. In some embodiments, multiple control units may be disposed on the same side or different sides of the electronic component group 118, but the present disclosure is not limited thereto.

As shown in FIG. 2, in some embodiments, the electronic component 21 of the electronic component group 118 may be, for example, electrically connected and adjacent to the first signal receiving end 200. The electronic component 23 may be, for example, electrically connected and adjacent to the second signal receiving end 202. The electronic component 25 may be, for example, electrically connected and adjacent to the third signal receiving end 204, but the present disclosure is not limited thereto. When it is mentioned that “a certain electronic component is electrically connected and adjacent to a certain signal receiving end”, it means that the signal received by this certain signal receiving end will be preferentially transmitted to this certain electronic component relative to other electronic components. In some embodiments, the second signal receiving end 202 is, for example, located between the first signal receiving end 200 and the third signal receiving end 204, but the present disclosure is not limited thereto. In some embodiments, for example, the electronic component group 118 receives a first power signal from the control unit 138 through the first signal receiving end 200 and/or the third signal receiving end 204, and receives a second power signal through the second signal receiving end 202, but the present disclosure is not limited thereto. In some embodiments, the first power signal is one within a working voltage (VDD) and a common connection voltage (VSS), and the second power signal is the other one within the working voltage and the common connection voltage, but the present disclosure is not limited thereto.

In some embodiments, the circuit substrate 102 may include a first transmission circuit 210 and a second transmission circuit 220, which are respectively electrically connected to each electronic component group in multiple electronic component groups. As shown in FIG. 2, the first transmission circuit 210 and the second transmission circuit 220 are respectively electrically connected to the electronic component group 118. In some embodiments, the first transmission circuit 210, for example, may be electrically connected to the first signal receiving end 200 and/or the third signal receiving end 204. The second transmission circuit 220, for example, may be electrically connected to the second signal receiving end 202. As shown in FIG. 2, the first transmission circuit 210 may include multiple first wires 212 and multiple second wires 214 electrically connected to the first wires 212. The first wires 212 extend, for example, along a first direction Y. The second wires 214 extend, for example, along a second direction X. The first direction Y is different from the second direction X, but the present disclosure is not limited thereto. In some embodiments, the first direction Y may be substantially perpendicular to the second direction X. In some embodiments, the second transmission circuit 220 may include multiple third wires 222 and multiple fourth wires 224 electrically connected to the third wires 222. The third wires 222 extend, for example, along the first direction Y. The fourth wires 224 extend, for example, along the second direction X, but the present disclosure is not limited thereto.

In some embodiments, a part of the first wires 212 of the first transmission circuit 210 may be electrically connected to the first signal receiving end 200 and/or the third signal receiving end 204. The part of the first wires 212 can be used to transmit the power signal received from the first signal receiving end 200 and/or the third signal receiving end 204 to the electronic components electrically connected to the part of the first wires 212 (e.g., the electronic components 1˜25), but the present disclosure is not limited thereto. In some embodiments, a part of the third wires 222 of the second transmission circuit 220 may be electrically connected to the second signal receiving end 202. The part of the third wires 222 can be used to transmit the power signal received from the second signal receiving end 202 to the electronic components electrically connected to the part of the third wires 222 (e.g., the electronic components 1˜25).

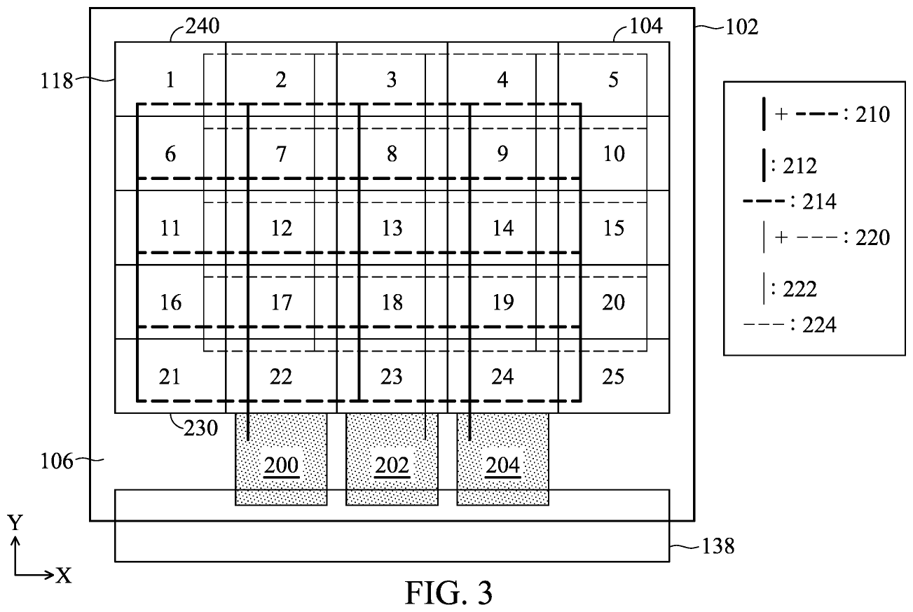

FIG. 3 is a schematic diagram of one of the multiple electronic components of the electronic device 100 in FIG. 1 in accordance with some embodiments of the present disclosure. In FIG. 3, the present disclosure is exemplified by the electronic component group 118 among the multiple electronic component groups. The difference between FIG. 3 and FIG. 2 is that the electronic component 22 of the electronic component group 118 may be electrically connected and adjacent to the first signal receiving end 200, the electronic component 23 may be electrically connected and adjacent to the second signal receiving end 202, and the electronic component 24 may be electrically connected and adjacent to the third signal receiving end 204. Compared with FIG. 1, the first signal receiving end 200 and the third signal receiving end 204 in FIG. 3 are, for example, closer to the second signal receiving end 202. The distance between the first signal receiving end 200 and the third signal receiving end 204 in the second direction X is reduced, but it is not limited thereto. The above distance may be defined as the minimum distance between the first signal receiving end 200 and the third signal receiving end 204 in the second direction X. In other embodiments (not shown), the distance between the first signal receiving end 200 and the second signal receiving end 202, and the distance between the third signal receiving end 204 and the second signal receiving end 202 are different in the second direction X. The above distance can be defined as the minimum distance between the first signal receiving end 200 and the second signal receiving end 202, and between the third receiving end 204 and the second signal receiving end 202 in the second direction X.

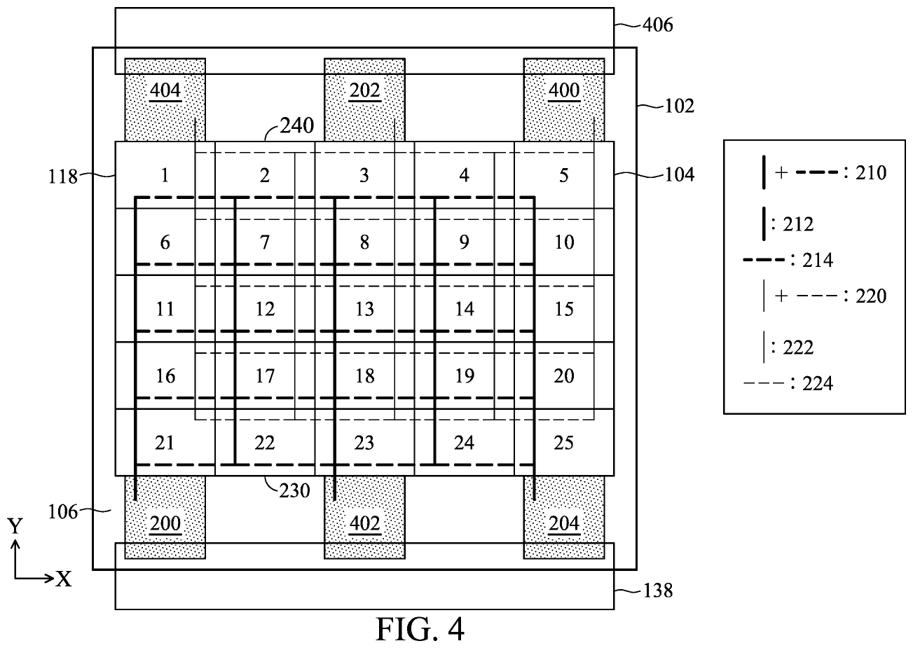

FIG. 4 is a schematic diagram of one of the multiple electronic components of the electronic device 100 in FIG. 1 in accordance with some embodiments of the present disclosure. In FIG. 4, the present disclosure is exemplified by the electronic component group 118 among the multiple electronic component groups. As shown in FIG. 4, multiple electronic component groups may receive two power signals from the control circuit (for example, the control unit 138 and/or the control unit 406) through N signal receiving ends. The N signal receiving ends include the first signal receiving end 200, the second signal receiving end 202, and the third signal receiving end 204, and N is an even number greater than 3. In some embodiments, the circuit substrate 120 has the first transmission circuit 210 and the second transmission circuit 220, which are respectively electrically connected to one of the multiple electronic component groups (for example, the electronic component group 118). The first transmission circuit 210 may be electrically connected to a part of the N signal receiving ends, and the second transmission circuit 220 may be electrically connected to the other part of the N signal receiving ends. In some embodiments, the electronic component group 118 may receive one power signal from the control unit 138 through the part of the N signal receiving ends, and receive another power signal from the control unit 406 through the other part of the N signal receiving ends, but the present disclosure is not limited thereto. For example, the first signal receiving end 200, the third signal receiving end 204, and/or the fifth signal receiving end 402 may, for example, receive a power signal from the control unit 138 of the control circuit. The second signal receiving end 202, the fourth signal receiving end 400, and/or the sixth signal receiving end 404 may, for example, receive another power signal from the control unit 406 of the control circuit, but the present disclosure is not limited thereto. In some embodiments, a part of the N signal receiving ends are disposed on the inactive area 106 and adjacent to the first side 230 of one of the multiple electronic component groups (for example, the electronic component group 118). The other part of the N signal receiving ends are disposed on the inactive area 106 and adjacent to the second side 240 of one of the multiple electronic component groups (for example, the electronic component group 118). The second side 240 is opposite the first side 230. For example, the first signal receiving end 200, the third signal receiving end 204, and/or the fifth signal receiving end 402 may, for example, the first signal receiving end 200, the third signal receiving end 204, and/or the fifth signal receiving end 402 may be, for example, disposed on the inactive area 106 and adjacent to the first side 230 of the electronic component group 118. The second signal receiving end 202, the fourth signal receiving end 400, and/or the sixth signal receiving end 404 may be, for example, disposed on the inactive area 106 and adjacent to the second side 240 of the electronic component group 118, but the present disclosure is not limited thereto. In some embodiments (not shown), the numbers of signal receiving ends adjacent to the first side 230 and the second side 240 of the electronic component group 118 may be the same or different.

Referring to FIG. 4, in some embodiments, the electronic component 21 of the electronic component group 118 may be electrically connected and adjacent to the first signal receiving end 200. The electronic component 23 may be electrically connected and adjacent to the fifth signal receiving end 402. The electronic component 25 may be electrically connected and adjacent to the third signal receiving end 204. The electronic component 1 may be electrically connected and adjacent to the sixth signal receiving end 404. The electronic component 3 may be electrically connected and adjacent to the second signal receiving end 202. The electronic component 5 may be electrically connected and adjacent to the fourth signal receiving end 400, but the present disclosure is not limited thereto. In some embodiments, the first transmission circuit 210 may electrically connected to the first signal receiving end 200, the fifth signal receiving end 402, and/or the third signal receiving end 204. In some embodiments, the second transmission circuit 220 may be electrically connected to the sixth signal receiving end 404, the second signal receiving end 202, and/or the fourth signal receiving end 400, but the present disclosure is not limited thereto. In some embodiments, the electronic component group 118 may receive one within the working voltage (VDD) and the common connection voltage (VSS) from the control unit 138 through the first signal receiving end 200, the fifth signal receiving end 402, and/or the third signal receiving end 204, but the present disclosure is not limited thereto. In some embodiments, the electronic component group 118 may receive the other one within the working voltage (VDD) and the common connection voltage (VSS) from the control unit 406 through the sixth signal receiving end 404, the second signal receiving end 202, and/or the fourth signal receiving end 400, but the present disclosure is not limited thereto. Although FIG. 4 discloses that the first power signal (one within the working voltage and the common connection voltage) from the control unit 138 is received through three signal receiving ends adjacent to the first side 230, and the second power signal (the other one within the working voltage and the common connection voltage) from the control unit 406 is received through the other three signal receiving ends adjacent to the second side 240, but the present disclosure is not limited thereto. The present disclosure does not limit the number of signal receiving ends adjacent to different sides of electronic component group 118, the types of power signals of signal receiving ends, or the connection methods of signal receiving ends and electronic component ends. In other embodiments (not shown), the number of signal receiving ends electrically connected to the second transmission circuit 220 may be the same or different than the number of signal receiving ends electrically connected to the first transmission circuit 210. In other embodiments (not shown), the receiving ends that receive the same power signal may be adjacent to the same side or different sides of the electronic component group. For example, the receiving ends that receive the same power signal may be adjacent to the first side 230 and/or the second side 240 of the electronic component group 118.

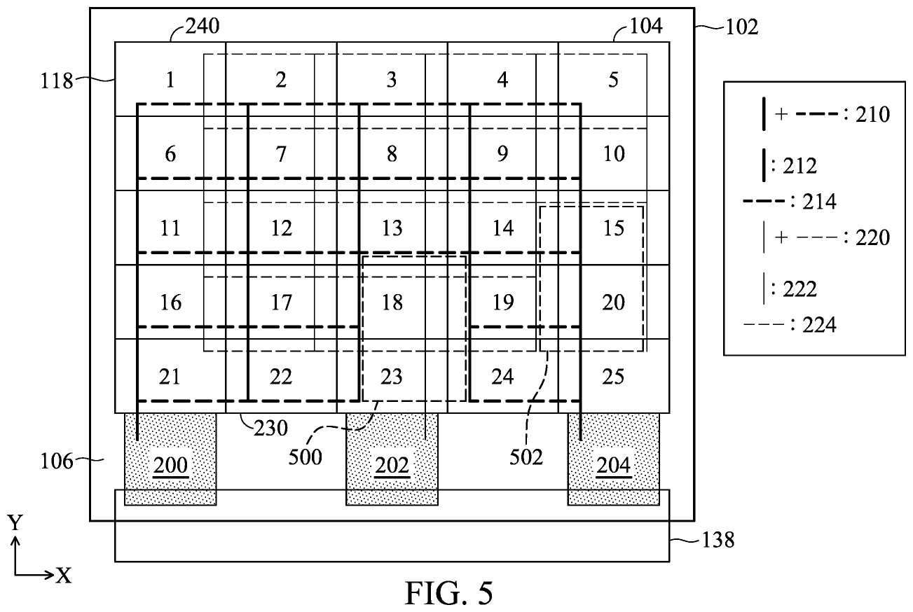

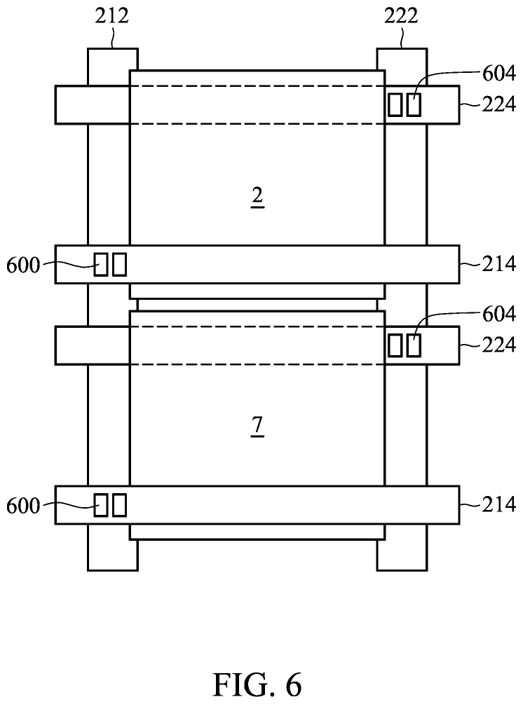

FIG. 5 is a schematic diagram of one of the multiple electronic components having a circuit cut-off region of the electronic device 100 in FIG. 1 in accordance with some embodiments of the present disclosure. FIGS. 6, 7, and 8 are circuit layout diagrams of some electronic components in FIG. 5 in accordance with some embodiments of the present disclosure.

In FIG. 5, the present disclosure is exemplified by the electronic component group 118, which is one of the multiple electronic component groups. The difference between FIG. 5 and FIG. 2 is that the first transmission circuit 210 may have, for example, a wire cut-off region 500 (e.g., the cut-off region of the second wires 214), or the second transmission circuit 220 may have, for example, a wire cut-off region 502 (e.g., the cut-off region of the fourth wires 224), but the present disclosure is not limited thereto. Using the design described above, some electronic components included in the electronic component group 118 may not correspond to the multiple second wires 214 or the multiple fourth wires 224. For more detail, please refer to FIG. 2. In FIG. 2, for example, the electronic components 1˜25 may not correspond to any wire cut-off region 500. In other words, the electronic components 1˜25 may correspond to the first wires 212 and the second wires 214, respectively. Thus, the electronic components 1˜25 may respectively receive a power signal from the control unit 138 through the two paths of the first wires 212 and the second wires 214. The power signal may be, for example, the power signal received by the first signal receiving end 200 and the third signal receiving end 204. In addition, the electronic components 1˜25, for example, may not correspond to any wire cut-off region 502. In other words, the electronic components 1˜25 may correspond to the third wires 222 and the fourth wires 224, respectively. Thus, the electronic components 1˜25 may respectively receive the other power signal from the control unit 138 through the two paths of the third wires 222 and the fourth wires 224. The other power signal may be, for example, the power signal received by the second signal receiving end 202.

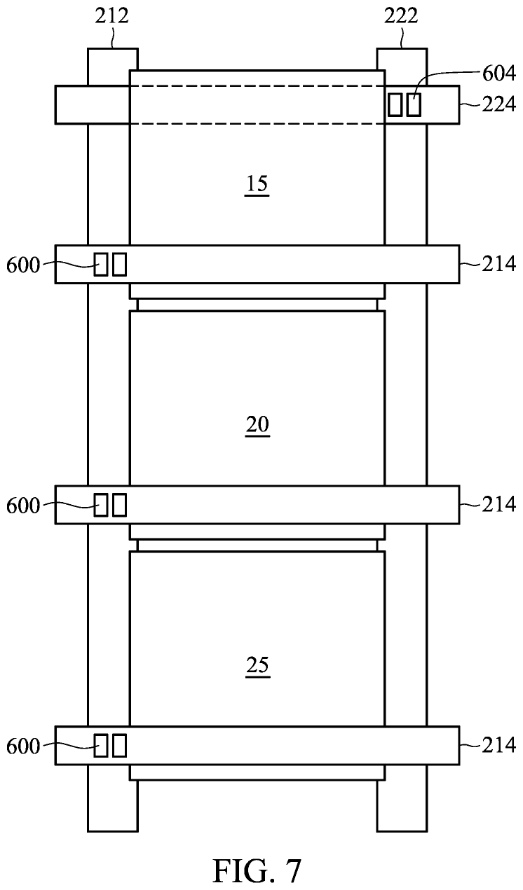

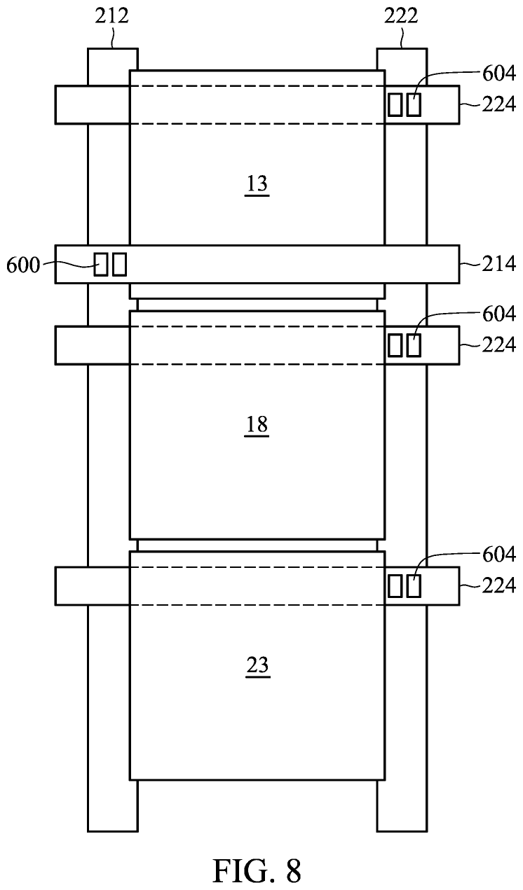

In FIG. 5, the first transmission circuit 210 may have a wire cut-off region 500. The electronic components 23 and/or the electronic components 18 corresponding to the wire cut-off region 500, for example, may not correspond to any second wires 214. For details, please refer to the description of the subsequent FIG. 8. In addition, the second transmission circuit 220 may have a wire cut-off region 502. The electronic components 25 and/or the electronic components 20 corresponding to the wire cut-off region 502, for example, may not correspond to any fourth wires 224. For details, please refer to the description of the subsequent FIG. 7. In the present disclosure, “the electronic component 23 does not correspond any second wires 214” means that the electronic component 23 does not receive the power signal from the control unit through the path of the second wires 214. In other words, the electronic component 23 receives the power signal from the control unit through the path of the first wires 212, and so on. In the present disclosure, “the electronic component 25 does not correspond any fourth wires 224” means that the electronic component 25 does not receive the power signal from the control unit through the path of the fourth wires 224. In other words, the electronic component 25 receives the power signal from the control unit through the path of the third wires 222, and so on. The current uniformity of the electronic components 1˜25 can be improved through the design of the wire cut-off region 500 and/or the wire cut-off region 502.

It should be noted that, since the first wires 212 and the second wires 214 of the first transmission circuit 210 can transmit the power signal from the first signal receiving end 200 and/or the third signal receiving end 204 to the electronic components 1˜25, in order to enable the electronic components 1˜25 to receive the power signal, the electronic components corresponding to the wire cut-off region 500 cannot be the electronic components corresponding to the first wires 212 connected to the first signal receiving end 200 and/or the third signal receiving end 204. Specifically, the electronic components corresponding to the first wires 212 connected to the first signal receiving end 200 in FIG. 5 are, for example, the electronic components 21, 16, 11, 6 and 1. The electronic components corresponding to the first wires 212 connected to the third signal receiving end 204 are, for example, the electronic components 25, 20, 15, 10 and 5. Therefore, the above-mentioned electronic components are not the electronic components corresponding to the wire cut-off region 500 (e.g. the electronic components 23 and/or the electronic components 18). Using the design described above, the electronic components 1˜25 can all receive the power signal, thereby contributing to the uniformity of current transmission to the electronic components.

Similarly, since the third wires 222 and the fourth wires 224 of the second transmission circuit 220 can transmit the power signal from the second signal receiving end 202 to the electronic components 1˜25, the electronic components corresponding to the wire cut-off region 502 cannot be the electronic components corresponding to the third wires 222 connected to the second signal receiving end 202. Specifically, the electronic components corresponding to the third wires 222 connected to the second signal receiving end 202 may, for example, be electronic components 23, 18, 13, 8 and 3. Therefore, the above-mentioned electronic components are not the electronic components corresponding to the wire cut-off region 502 (e.g. the electronic components 25 and/or the electronic components 20). Using the design described above, the electronic components 1˜25 can all receive the power signal, thereby contributing to the uniformity of current transmission to the electronic components.

As shown in FIG. 6, for example, a circuit layout diagram of the electronic components 2 and 7 is shown. The electronic components 2 and 7, for example, may respectively correspond to the first wires 212 and the second wires 214 in the first transmission circuit 210. The electronic components 2 and 7, for example, may respectively correspond to the third wires 222 and the fourth wires 224 in the second transmission circuit 220. As shown in FIG. 6, the multiple first wires 212 in the first transmission circuit 210 may be electrically connected to the multiple second wires 214 through at least one first through hole 600, respectively. On the other hand, the third wires 222 in the multiple second transmission circuits may be electrically connected to the fourth wires 224 through at least one second through hole 604. In some embodiments, the first wires 212 and the second wires 214 in the first transmission circuit 210 may be disposed on different layers, for example. The third wires 222 and the fourth wires 224 in the second transmission circuit 220 may be disposed on different layers, for example. In some embodiments, the electronic components (e.g., the electronic components 2 and 7) not corresponding to the wire cut-off region 500 may overlap with the corresponding first wires 212 and/or the corresponding second wires 214, for example, but the present disclosure is not limited thereto. In some embodiments, the electronic components (e.g., the electronic components 2 and 7) not corresponding to the wire cut-off region 502 may overlap with the corresponding third wires 222 and/or the corresponding fourth wires 224, for example, but the present disclosure is not limited thereto. In some embodiments, the first wires 212 and the third wires 222 may be located on different sides of the corresponding electronic components, for example. In some embodiments, the second wires 214 and the fourth wires 224 may be located on different sides of the corresponding electronic components, for example.

FIG. 7 is, for example, a circuit layout diagram of the electronic components 25, 20, and 15. The electronic components 25 and 20 are, for example, the electronic components corresponding to the wire cut-off region 502. As shown in FIG. 7, the electronic components 25 and 20 corresponding to the wire cut-off region 502 may have no fourth wires 224 connected or corresponding to the electronic components 25 and 20. Therefore, for example, the electronic components 25 and 20 do not receive the power signal from the control unit 138 through the fourth wires 224, but only receive the power signal from the control unit 138 through the third wires 222, but the present disclosure is not limited thereto.

FIG. 8 is, for example, a circuit layout diagram of the electronic components 23, 18, and 13. The electronic components 23 and 18 are, for example, the electronic components corresponding to the wire cut-off region 500. As shown in FIG. 8, the electronic components 23 and 18 corresponding to the wire cut-off region 500 may have no second wires 214 connected or corresponding to the electronic components 23 and 18. Therefore, for example, the electronic components 23 and 18 do not receive the power signal from the control unit 138 through the second wires 214, but only receive the power signal from the control unit 138 through the first wires 212, but the present disclosure is not limited thereto.

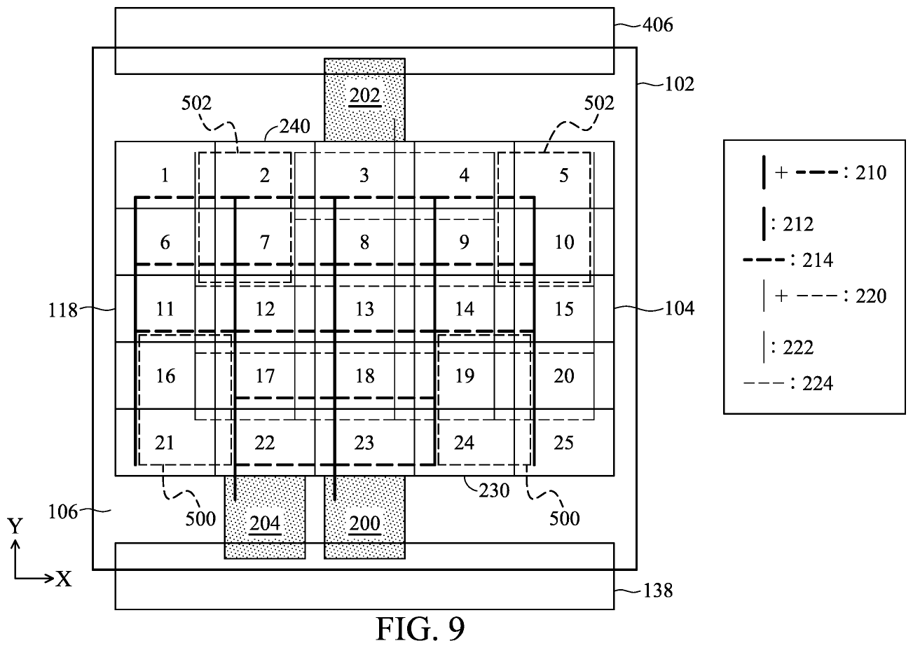

FIG. 9 is a schematic diagram of one of the multiple electronic components of the electronic device 100 in FIG. 1 in accordance with some embodiments of the present disclosure. FIG. 9 takes the electronic component group 118 among multiple electronic component groups as an example. The electronic component group 118 may include electronic components 1˜25. In some embodiments, the electronic component group 118 may receive a power signal from the control unit 138 through the first signal receiving end 200 and/or the third signal receiving end 204 adjacent to the first side 230. The electronic component group 118 may receive the other power signal from the control unit 406 through the second signal receiving end 202 adjacent to the second side 240. The first side 230 is opposite the second side 240.

In FIG. 9, the electronic component 23 of the electronic component group 118, for example, is electrically connected and adjacent to the first signal receiving end 200. The electronic component 3 of the electronic component group 118 is electrically connected and adjacent to the second signal receiving end 202. The electronic component 22 of the electronic component group 118 is electrically connected and adjacent to the third signal receiving end 204, but the present disclosure is not limited thereto. The electronic components electronically connected to the first signal receiving end 200, the second signal receiving end 202, and/or the third signal receiving end 204 can be changed according to the requirement. In some embodiments, the circuit substrate 102 may include the first transmission circuit 210 and the second transmission circuit 220. The first transmission circuit 210 may be electrically connected to the first signal receiving end 200 and/or the third signal receiving end 204. The second transmission circuit 220 may be electrically connected to the second signal receiving end 202. In some embodiments, the first transmission circuit 210 in FIG. 9 has the wire cut-off region 500, and the second transmission circuit 220 has the wire cut-off region 502, but the present disclosure is not limited thereto. In some embodiments, the multiple wire cut-off regions 500, for example, may correspond to electronic components located in different areas, and the electronic components in these different areas may be selectively separated from each other, but the present disclosure is not limited thereto. For example (as shown in FIG. 9), one wire cut-off region 500 may correspond to, for example, the electronic component 25 and the electronic component 20. The other wire cut-off region 502 may correspond to, for example, the electronic component 21 and the electronic component 16, but the present disclosure is not limited thereto. In some embodiments, the multiple wire cut-off regions 502 may, for example, correspond to the electronic components located in different areas. For example (as shown in FIG. 9), one wire cut-off region 502 may correspond to the electronic component 5 and the electronic component 10. The other wire cut-off region 502 may correspond to the electronic component 1 and the electronic component 6, but the present disclosure is not limited thereto. In other embodiments (not shown), the number of wire cut-off regions 500 and the number of wire cut-off regions 502 may be the same or different. In other embodiments (not shown), the number of electronic components corresponding to the multiple wire cut-off regions 500 may be the same or different. In other embodiments (not shown), the number of electronic components corresponding to the multiple wire cut-off regions 502 may be the same or different. In some embodiments, the electronic components electrically connected and adjacent to the first signal receiving end 200 may be, for example, the electronic components in the same column as the electronic components electrically connected and adjacent to the second signal receiving end 202. The electronic components located in the same column are arranged along the first direction Y, for example, the electronic components 23, 18, 13, 8 and 3 are the electronic components located in the same column. In other embodiments (not shown), the electronic components electrically connected and adjacent to the first signal receiving end 200 may be, for example, the electronic components in different columns from the electronic components electrically connected and adjacent to the second signal receiving end 202. In some embodiments, the electronic components electrically connected and adjacent to the third signal receiving end 204 may be, for example, the electronic components in different columns from the electronic components electrically connected and adjacent to the second signal receiving end 202

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
multiple electronic component groups; and
a control circuit, electrically connected the electronic component groups;
wherein one of the electronic component groups receives two power signals from the control circuit through a first signal receiving end, a second signal receiving end, and a third signal receiving end.

2. The electronic device as claimed in claim 1, further comprising:
a circuit substrate having an active area and an inactive area adjacent to the active area;
wherein the electronic component groups are disposed on the active area, the first signal receiving end, the second signal receiving end, and the third signal receiving end are disposed on the inactive area and adjacent to one side of the one of the electronic component groups.

3. The electronic device as claimed in claim 2, wherein the second signal receiving end is located between the first signal receiving end and the third signal receiving end, the first signal receiving end receives a first power signal, and the second signal receiving end receives a second power signal.

4. The electronic device as claimed in claim 3, wherein the first power signal is one within a working voltage and a common connection voltage, and the second power signal is the other one of the working voltage and the common connection voltage.

5. The electronic device as claimed in claim 3, wherein
the circuit substrate has a first transmission circuit and a second transmission circuit, which are respectively electrically connected to the one of the electronic component groups; the first transmission circuit is electrically connected to the first signal receiving end and the third signal receiving end, the second transmission circuit is electrically connected to the second signal receiving end;
the first transmission circuit has multiple first wires and multiple second wires electrically connected to the first wires; the second transmission circuit has multiple third wires and multiple fourth wires electrically connected to the third wires;
wherein the one of the electronic component groups comprises multiple electronic components, and some of the multiple electronic components do not correspond to the second wires or the fourth wires.

6. The electronic device as claimed in claim 5, wherein the first wires are electrically connected to the second wires through a first through hole, and the third wires are electrically connected to the fourth wires through a second through hole.

7. The electronic device as claimed in claim 1, further comprising:
a circuit substrate having an active area and an inactive area adjacent to the active area;
wherein the electronic component groups are disposed on the active area, the second signal receiving end is disposed on the inactive area and adjacent to a first side of the one of the electronic component groups, the first signal receiving end and the third signal receiving end are disposed on the inactive area and adjacent to a second side of the one of the electronic component groups, and the second side is opposite the first side.

8. The electronic device as claimed in claim 7, wherein
the circuit substrate has a first transmission circuit and a second transmission circuit, which are electrically connected to the one of the electronic component groups;
the first transmission circuit is electrically connected to the first signal receiving end and the third signal receiving end,
the second transmission circuit is electrically connected to the second signal receiving end,
the first transmission circuit has multiple first wires and multiple second wires electrically connected to the first wires;
the second transmission circuit has multiple third wires and multiple fourth wires electrically connected to the third wires;
wherein the one of the electronic component groups comprises multiple electronic components, and some of the multiple electronic components do not correspond to the second wires or the fourth wires.

9. The electronic device as claimed in claim 1, further comprising:
a circuit substrate having an active area and an inactive area adjacent to the active area;
wherein the electronic component groups are disposed on the active area,
the electronic component groups comprise N signal receiving ends, the N signal receiving ends comprise the first signal receiving end, the second signal receiving end, and the third signal receiving end, and N is an even number greater than 3,
wherein a part of the N signal receiving ends are disposed on the inactive area and adjacent to a first side of the one of the electronic component groups, and the other part of the N signal receiving ends are disposed on the inactive area and adjacent to a second side of the one of the electronic component groups, and the second side is opposite the first side.

10. The electronic device as claimed in claim 9, wherein
the circuit substrate has a first transmission circuit and a second transmission circuit, which are respectively electrically connected to the one of the electronic component groups;
the first transmission circuit is electrically connected to the part of the N signal receiving ends,
the second transmission circuit is electrically connected to the other part of the N signal receiving ends,
the first transmission circuit has multiple first wires and multiple second wires electrically connected to the first wires,
the second transmission circuit has multiple third wires and multiple fourth wires electrically connected to the third wires,
wherein the one of the electronic component groups comprises multiple electronic components, and some of the multiple electronic components do not correspond to the second wires or the fourth wires.

11. The electronic device as claimed in claim 5, wherein some of the multiple electronic components do not receive the first power signal through the second wires, or do not receive the second power signal through the fourth wires.

12. The electronic device as claimed in claim 8, wherein the first signal receiving end and the third signal receiving end receive a first power signal, and the second signal receiving end receives a second power signal.

13. The electronic device as claimed in claim 12, wherein some of the multiple electronic components do not receive the first power signal through the second wires, or do not receive the second power signal through the fourth wires.

14. The electronic device as claimed in claim 10, wherein some of the multiple electronic components do not receive one of the two power signals through the second wires, or do not receive the other one of the two power signals through the fourth wires.

15. The electronic device as claimed in claim 5, wherein the first wires and the second wires in the first transmission circuit are disposed on different layers, and the third wires and the fourth wires in the second transmission circuit are disposed on different layers.

16. The electronic device as claimed in claim 5, wherein the first transmission circuit has a first wire cut-off region, and the second transmission circuit has a second wire cut-off region.

17. The electronic device as claimed in claim 16, wherein the electronic components corresponding to the first wire cut-off region do not have second wires, and the electronic components corresponding to the second wire cut-off region do not have fourth wires.

18. The electronic device as claimed in claim 16, wherein the electronic components not corresponding to the first wire cut-off region overlap with the first wires and/or the second wires.

19. The electronic device as claimed in claim 16, wherein the electronic components not corresponding to the second wire cut-off region overlap with the third wires and/or the fourth wires.

20. The electronic device as claimed in claim 10, wherein the number of parts of the N signal receiving ends electrically connected to the first transmission circuit and the number of other parts of the N signal receiving ends electrically connected to the second transmission circuit are the same or different.
